(19) United States
(12) Patent Application Publication
(10) Pub. No.: US 2005/0136588 A1
(43) Pub. Date: Jun. 23, 2005

(54) Method of forming isolation regions

(76) Inventor: Chris Speyer, Austin, TX (US)

Correspondence Address: WILLIAMS, MORGAN & AMERSON, P.C., 10333 RICHMOND, SUITE 1100, HOUSTON, TX, 77042, US

(21) Appl. No.: 10/744,622

(22) Filed: Dec. 23, 2003

(51) Int. Cl. H01L 21/44

(52) U.S. Cl. 438/221; 438/520

(57) ABSTRACT

The present invention is generally directed to various methods of forming isolation regions. In one illustrative embodiment, the method comprises forming a stack of process layers above a surface of a semiconducting substrate, the stack of process layers comprised of a first layer of insulating material formed above a surface of the substrate, an etch stop layer positioned above the first layer of insulating material, wherein the etch stop layer has an etch selectivity with respect to the first layer of insulating material of at least 3:1, and a second layer of insulating material positioned above the etch stop layer. The method further comprises performing at least one etching process to define an opening that extends through the stack of process layers to thereby expose a portion of the surface of the substrate, forming sidewall spacers in the opening in the stack of process layers, wherein the sidewall spacers are comprised of a material having an etch selectivity with respect to the first layer of insulating material of at least 3:1, performing at least one etching process to define a trench in the substrate using the sidewall spacers as a portion of a mask during the etching process, removing the second layer of insulating material, forming a liner layer comprised of an insulating material on at least the sidewalls of the trench, performing at least one etching process to remove the sidewall spacers and the etch stop layer, and forming additional material in the trench adjacent the liner layer.

### BACKGROUND OF THE INVENTION

1. Field of the Invention

This invention relates generally to the fabrication of semiconductor devices, and, more particularly, to a method of forming isolation regions.

2. Description of the Related Art

It is often desirable to electrically isolate semiconductor devices from one another in an integrated circuit product. One way to achieve such isolation is by utilizing insulator filled vertical trenches in the semiconductor substrate to circumscribe the semiconductor devices, thereby isolating the semiconductor device from adjacent semiconductor devices. In some applications, particularly high voltage semiconductor devices, semiconductor devices are formed on silicon-on-insulator (SOI) substrates wherein the SOI substrate comprises a bulk substrate, a buried insulation layer, i.e., a so-called “box” layer, and an active layer formed above the box layer. In such applications, the vertical trenches are formed such that they intersect the underlying buried insulation layer to completely surround and electrically isolate the high voltage semiconductor devices.

Proper formation of such isolation regions can be critical in modern semiconductor devices. Poorly formed isolation structures may lead to reduced device performance, e.g., increased leakage currents. Moreover, the field of semiconductor manufacturing is a very competitive industry. Thus, there is constant pressure to develop new and improved processes for manufacturing the devices so that product yields may be increased and/or costs may be reduced. Existing methodologies for forming such isolation structures are relatively complex and time-consuming. Moreover, existing methodologies may have a greater tendency to produce defective devices due to the complex nature of such methodologies.

The present invention is directed to a method that may solve, or at least reduce, some or all of the aforementioned problems.

### SUMMARY OF THE INVENTION

The present invention is generally directed to various methods of forming isolation regions. In one illustrative embodiment, the method comprises forming a stack of process layers above a surface of a semiconducting substrate, the stack of process layers comprised of a first layer of insulating material formed above a surface of the substrate, an etch stop layer positioned above the first layer of insulating material, wherein the etch stop layer has an etch selectivity with respect to the first layer of insulating material of at least 3:1, and a second layer of insulating material positioned above the etch stop layer. The method further comprises performing at least one etching process to define an opening that extends through the stack of process layers to thereby expose a portion of the surface of the substrate, forming sidewall spacers in the opening in the stack of process layers, wherein the sidewall spacers are comprised of a material having an etch selectivity with respect to the first layer of insulating material of at least 3:1, performing at least one etching process to define a trench in the substrate using the sidewall spacers as a portion of a mask during the etching process, removing the second layer of insulating material, forming a liner layer comprised of an insulating material on at least the sidewalls of the trench, performing at least one etching process to remove the sidewall spacers and the etch stop layer, and forming additional material in the trench adjacent the liner layer.

In another illustrative embodiment, the method comprises forming a stack of process layers above a semiconducting substrate, the stack of process layers comprised of a first layer of silicon dioxide formed above a surface of the substrate, an etch stop layer comprised of silicon nitride positioned above the first layer of silicon dioxide, and a second layer of silicon dioxide positioned above the etch stop layer. The method further comprises performing at least one etching process to define an opening that extends through the stack of process layers to thereby expose a portion of the surface of the substrate, forming sidewall spacers comprised of silicon nitride in the opening in the stack of process layers, performing at least one etching process to define a trench in the substrate using the sidewall spacers as a portion of a mask during the etching process, removing the second layer of silicon dioxide, performing a thermal growth process to form a liner layer comprised of silicon dioxide on at least the sidewalls of the trench, performing at least one etching process to remove the sidewall spacers and the etch stop layer, and depositing additional material in the trench adjacent the liner layer.

In yet another illustrative embodiment, the method comprises forming a first layer of silicon dioxide on a surface of a semiconducting substrate, forming a first layer of silicon nitride on the first layer of silicon dioxide, forming a second layer of silicon dioxide on the first layer of silicon nitride, performing at least one etching process to define an opening through the first layer of silicon dioxide, the first layer of silicon nitride and the second layer of silicon dioxide to thereby expose a portion of the surface of the substrate, forming a second layer of silicon nitride above the second layer of silicon dioxide and in the opening, performing an anisotropic etching process on the second layer of silicon nitride to thereby define sidewall spacers comprised of silicon nitride in the opening, performing at least one etching process to define a trench in the substrate using the sidewall spacers as a portion of a mask during the etching process, performing at least one etching process to remove the second layer of silicon dioxide, forming a liner layer comprised of silicon dioxide on at least the sidewalls of the trench, performing at least one etching process to remove the first layer of silicon nitride and the sidewall spacers, and depositing additional material in the trench adjacent the liner layer.

### BRIEF DESCRIPTION OF THE DRAWINGS

The invention may be understood by reference to the following description taken in conjunction with the accompanying drawings, in which like reference numerals identify like elements, and in which:

FIG. 1 depicts an illustrative substrate having a plurality of process layers formed thereabove;

FIG. 2 depicts the device of FIG. 1 having an opening formed in the stack of process layers;

FIG. 3 depicts the device of FIG. 2 wherein a layer of spacer material has been formed in the opening formed in the process layers;

FIG. 4 depicts the device of FIG. 3 after sidewall spacers have been formed in the opening;

FIG. 5 depicts the device of FIG. 4 after a trench has been formed in the substrate;

FIG. 6 depicts the device of FIG. 5 after the uppermost process layer formed above the substrate has been removed;

FIG. 7 depicts the device of FIG. 6 wherein a sacrificial layer has been formed in the trench;

FIG. 8 depicts the situation wherein a liner layer has been formed on the sidewalls of the trench;

FIG. 9 depicts the situation wherein an etching process has been performed to remove one of the process layers formed above the substrate;

FIG. 10 depicts the device of FIG. 9 after a layer of silicon nitride and a layer of polysilicon has been formed thereabove; and

FIG. 11 depicts the device of FIG. 10 after a plurality of etching processes are performed to pattern the layer of silicon nitride and layer of polysilicon.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various layers and structures of the semiconductor device are depicted in the drawings as having very precise, sharp configurations and profiles, those skilled in the art recognize that, in reality, these regions and structures may not be as precise as indicated in the drawings. Additionally, the relative sizes of the various features and layers depicted in the drawings may be exaggerated or reduced as compared to the size of those features or layers on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In general, the present invention is directed to various methods of forming isolation regions. As will be readily apparent to those skilled in the art upon a complete reading of the present application, the present invention may be employed in connection with the formation of isolation regions employed on a variety of different semiconductor devices, e.g., memory devices, logic devices, etc. Moreover, the present invention may be employed with a variety of different technologies, e.g., CMOS, PMOS, NMOS devices, as well as Bipolar devices. Thus, the present invention should not be considered as limited to any particular type of device or other methodologies employed in forming such a semiconductor device unless such limitations are expressly set forth in the appended claims.

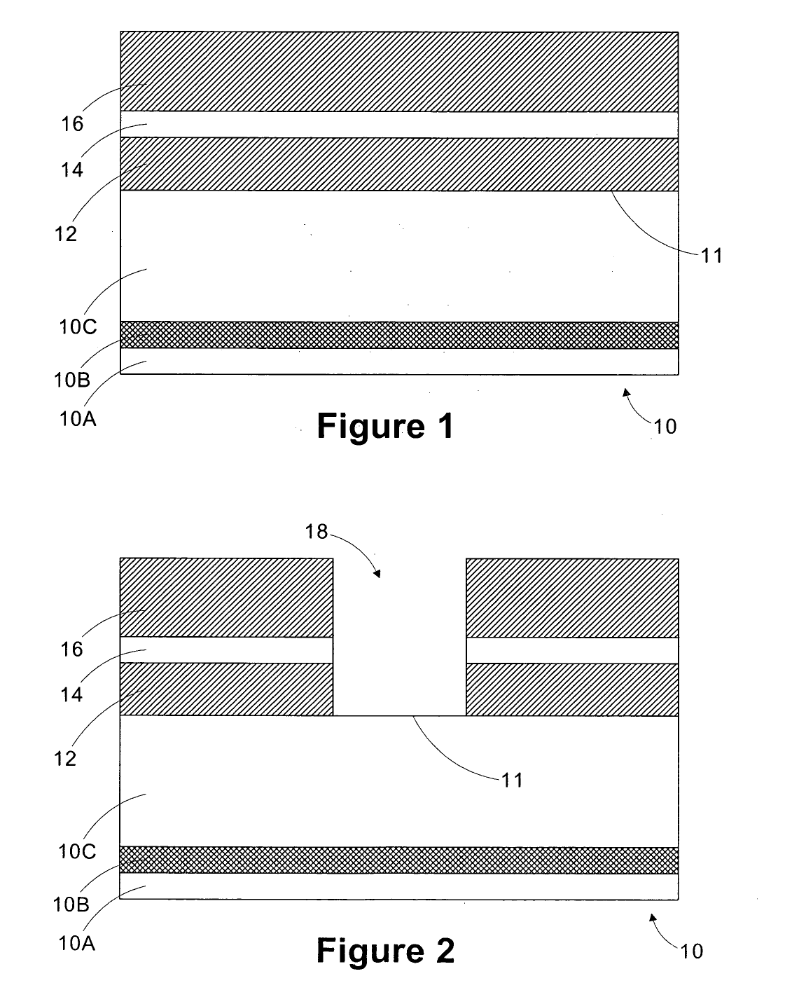

FIG. 1 depicts a plurality of process layers formed above an illustrative substrate 10. In the depicted embodiment, the substrate 10 is an illustrative silicon-on-insulator (SOI) substrate comprised of a bulk substrate 10a, a buried insulation layer 10b (a so-called “BOX” layer), and an active layer 10c. Semiconductor devices (not shown) are formed in and above the active layer 10c. As will be recognized by those skilled in the art after a complete reading of the present application, the present invention may be employed with a variety of substrate materials and substrate configurations. For example, if desired, the present invention may be employed with bulk silicon wafers. Moreover, the substrate 10 may be made of any of a variety of semiconducting materials. Thus, the present invention should not be considered as limited to the use with any type of substrate 10, or the configuration of such substrate, unless such limitations are expressly set forth in the appended claims.

As indicated in FIG. 1, a layer stack comprised of a plurality of process layers is formed above the surface 11 of the substrate 10. More specifically, in the depicted embodiment, a first layer of insulating material 12 is formed above the surface 11 of the substrate 10, an etch stop layer 14 is formed above the first layer of insulating material 12, and a second layer of insulating material 16 is formed above the etch stop layer 14. In an even more specific embodiment, the first layer of insulating material 12 is a field oxide layer. As will be recognized by those skilled in the art after a complete reading of the present application, the process layers 12, 14, 16 may be manufactured from a variety of materials and they may be manufactured using a variety of techniques. The first and second insulating layers 12, 16 may be comprised of a variety of insulating materials, e.g., silicon dioxide, silicon oxynitride, etc. Moreover, the first and second insulating layers 12, 16 may be comprised of different insulating materials. The etch stop layer 14 may also be comprised of a variety of different materials, e.g., silicon nitride, polysilicon, silicon oxynitride, or a metal. In general, the etch stop layer 14 should be comprised of a material that has an etch selectivity of at least 3:1 with respect to the first layer of insulating material 12. In one illustrative embodiment, the first layer of insulating material 12 is a thermally grown layer of silicon dioxide having a thickness of approximately 1 micron, the etch stop layer 14 is a layer of silicon nitride having a thickness of approximately 2000 Å that is formed by a chemical vapor deposition process, e.g., low pressure chemical vapor deposition (LPCVD), plasma enhanced chemical vapor deposition (PECVD), etc., and the second layer of insulating material 16 is a layer of silicon dioxide having a thickness of approximately 2-2.5 microns that is formed by a deposition process, e.g., CVD, LPCVD, PECVD, etc.

Next, as indicated in FIG. 2, an opening 18 is formed through the stack of process layers 12, 14, 16 to thereby expose a portion of the surface 11 of the substrate 10. The opening 18 is formed by performing at least one anisotropic etching process to etch through the various layers 12, 14, 16. A patterned layer of photoresist (not shown) is formed above the second layer of insulating material 16 in accordance with known photolithography techniques and used as a mask layer during the etching process. After the opening 18 is formed, the patterned layer of photoresist is then removed.

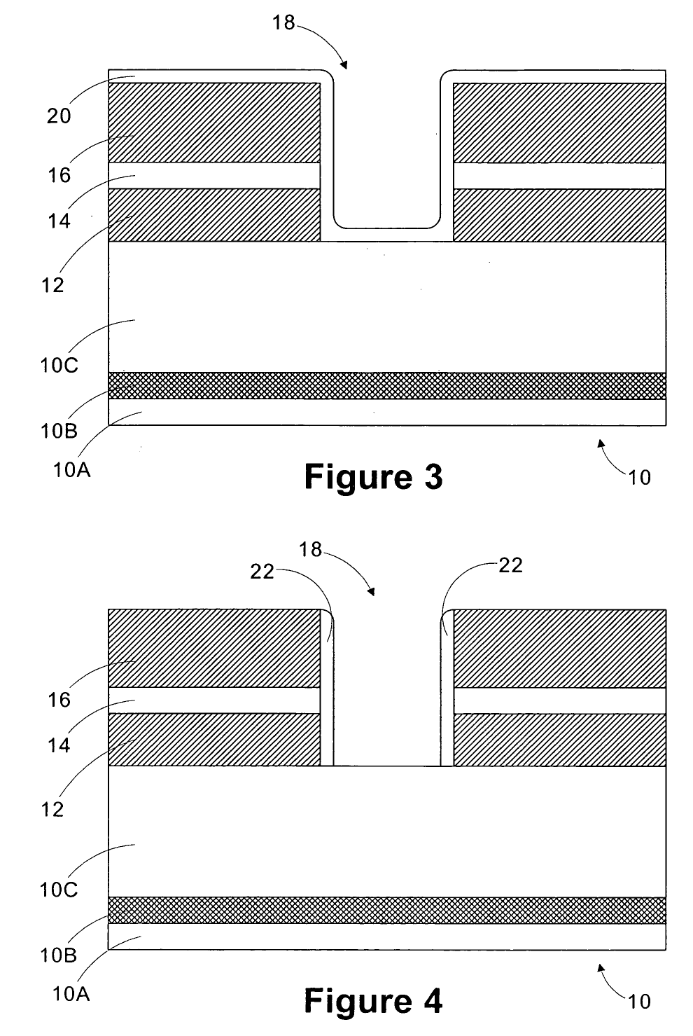

FIG. 3 depicts the device at a point of manufacture wherein a layer of spacer material 20 is deposited above the second insulating layer 16 and in the opening 18. The layer of spacer material 20 may be comprised of a variety of different materials, e.g., silicon nitride, silicon oxynitride, etc. In general, the layer of spacer material 20 should be comprised of a material that has an etch selectivity of at least 3:1 with respect to the material comprising the first insulating layer 12. In one illustrative embodiment, the layer of spacer material 20 is a layer of silicon nitride having a thickness of approximately 2000 Å that is formed by a chemical vapor deposition process, e.g., LPCVD, PECVD, etc.

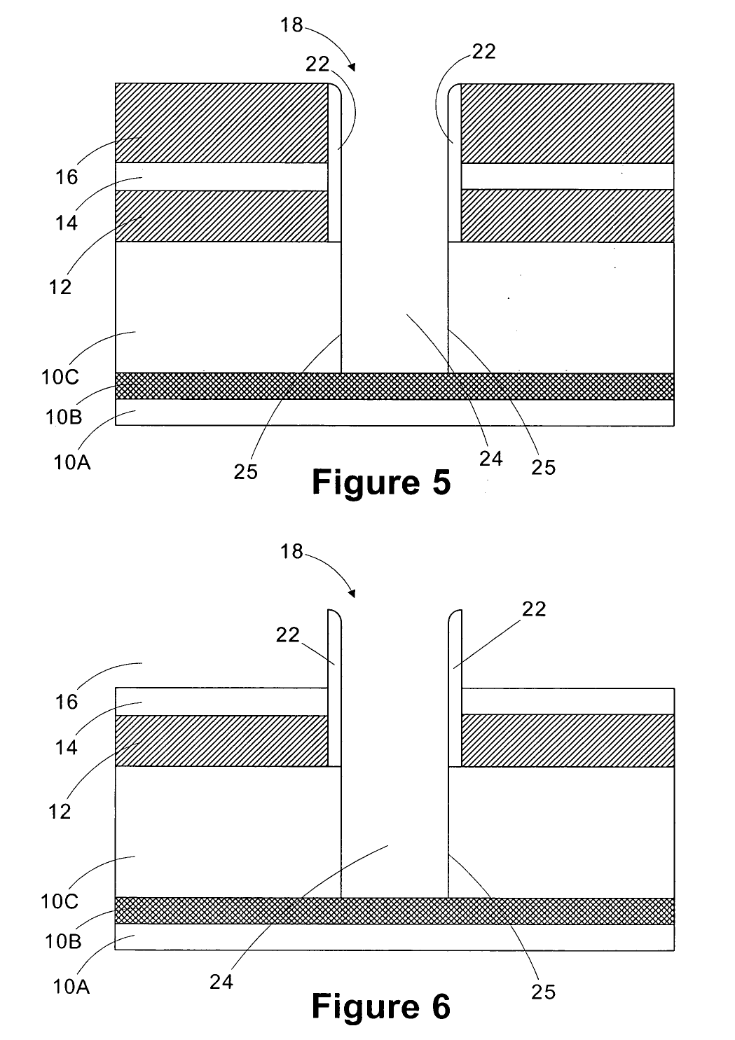

As indicated in FIG. 4, the next step involves formation of sidewall spacers 22 on the sidewalls of the opening 18. The sidewall spacers 22 are formed by performing an anisotropic etching process on the layer of spacer material 20. Thereafter, as indicated in FIG. 5, a trench 24 is formed in the substrate 10 by performing one or more anisotropic etching processes. The spacers 22 act as a portion of a mask during the one or more etching processes that are performed to form the trench 24. In the depicted embodiment where an SOI substrate is employed, the trench 24 may extend to the buried insulation layer 10b. The size of the trench 24 may vary depending upon the particular application. In one illustrative embodiment, e.g., for high voltage applications, the trench 24 may have a width of approximately 2 microns and a depth of approximately 26 microns. However, as will be recognized by those skilled in the art after a complete reading of the present application, the present invention may be employed in forming isolation structures wherein the trench 24 has a variety of different physical dimensions. Thus, the illustrative dimensional data provided herein should not be considered a limitation of the present invention unless such limitations are expressly set forth in the appended claims.

The next step involves removing the second layer of insulating material 16, as indicated in FIG. 6. The second layer of insulating material 16 may be removed by performing an etching process, e.g., a wet chemical stripping process, to remove the layer of insulating material 16. For example, where the second layer of insulating material 16 is comprised of silicon dioxide, a buffered oxide etch (BOE) process may be used to remove the second layer of insulating material 16.

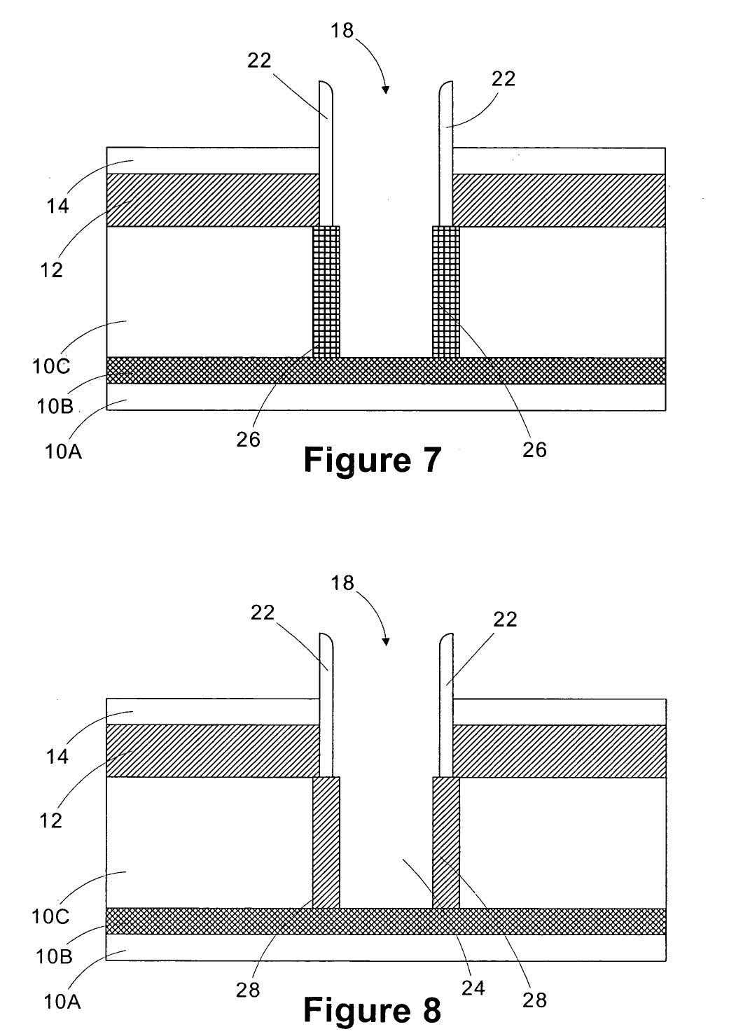

As indicated in FIG. 7, in one illustrative process flow, the next step involves the formation of a sacrificial layer 26 on at least the sidewalls 25 (see FIG. 5) of the trench 24. In one illustrative embodiment, the sacrificial layer 26 is a thermally grown layer of silicon dioxide. When employed, the sacrificial layer 26 is used to remove the damaged surface of the substrate on the sidewalls 25 of the trench 24. However, such a sacrificial layer 26 may not be employed in all applications. Thus, the present invention should not be considered as limited to the use of such a sacrificial layer 26 unless such limitations are clearly set forth in the appended claims. After the sacrificial layer 26 is formed, it may be removed by performing one or more etching processes, e.g., a wet chemical etching process.

As indicated in FIG. 8, in one illustrative process flow, a liner layer 28 is formed on at least the sidewalls 25 of the trench 24. The liner layer 28 may be comprised of a variety of insulating materials, e.g., silicon dioxide. In one illustrative embodiment, the liner layer 28 is comprised of a thermally grown layer of silicon dioxide having a thickness of approximately 4000-6000 Å.

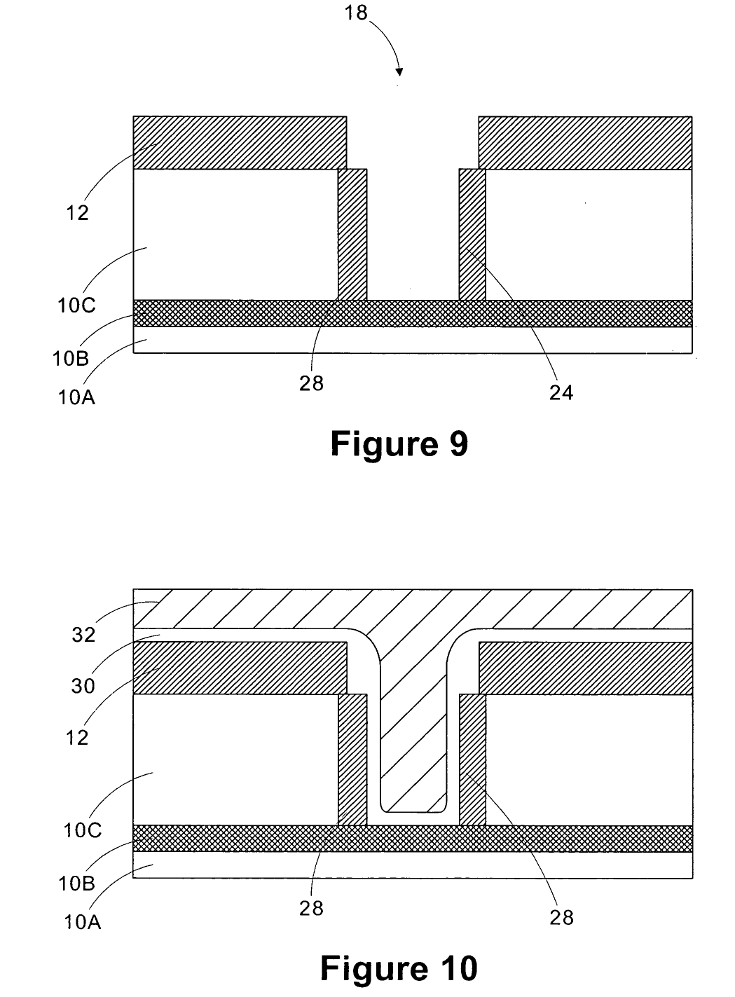

The next step in the illustrative process flow depicted herein involves removal of the etch stop layer 14 and the sidewall spacers 22. The resulting structure is depicted in FIG. 9. The etch stop layer 14 and the sidewall spacers 22 may be removed by performing one or more etching processes to remove such structures. For example, in the case where the etch stop layer 14 and the sidewall spacers 22 are comprised of silicon nitride, the structures may be removed by subjecting the device to a wet chemical bath using phosphoric acid.

Thereafter, the method of the present invention generally involves the formation of additional material in the trench adjacent the liner layer 28. This additional material may be comprised of a variety of different materials that may be positioned within the trench by a variety of techniques. In one illustrative embodiment depicted in FIG. 10, the method involves depositing a layer of silicon nitride 30 and a layer of polysilicon 32 in the trench and above the structure. The layers 30, 32 may be formed by performing well known deposition processes, e.g., LPCVD, PECVD, etc. The thickness of the layers 30, 32 may vary depending on the particular application. For example, in one illustrative embodiment, the layer of polysilicon 32 may have a thickness of approximately 2 microns.

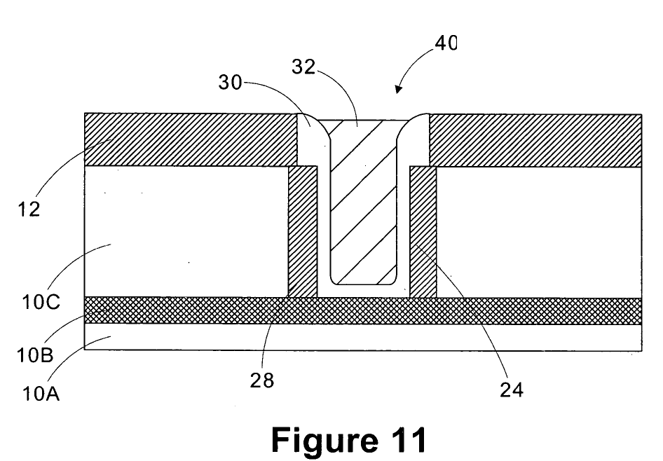

Thereafter, as shown in FIG. 11, one or more etching processes are performed on the layers 30, 32 to result in the isolation structure 40 depicted in FIG. 11. Further processing may be performed to complete the device in accordance with well known manufacturing techniques.

The present invention is generally directed to various methods of forming isolation regions. In one illustrative embodiment, the method comprises forming a stack of process layers above a surface of a semiconducting substrate, the stack of process layers comprised of a first layer of insulating material formed above a surface of the substrate, an etch stop layer positioned above the first layer of insulating material, wherein the etch stop layer has an etch selectivity with respect to the first layer of insulating material of at least 3:1, and a second layer of insulating material positioned above the etch stop layer. The method further comprises performing at least one etching process to define an opening that extends through the stack of process layers to thereby expose a portion of the surface of the substrate, forming sidewall spacers in the opening in the stack of process layers, wherein the sidewall spacers are comprised of a material having an etch selectivity with respect to the first layer of insulating material of at least 3:1, performing at least one etching process to define a trench in the substrate using the sidewall spacers as a portion of a mask during the etching process, removing the second layer of insulating material, forming a liner layer comprised of an insulating material on at least the sidewalls of the trench, performing at least one etching process to remove the sidewall spacers and the etch stop layer, and forming additional material in the trench adjacent the liner layer.

In another illustrative embodiment, the method comprises forming a stack of process layers above a semiconducting substrate, the stack of process layers comprised of a first layer of silicon dioxide formed above a surface of the substrate, an etch stop layer comprised of silicon nitride positioned above the first layer of silicon dioxide, and a second layer of silicon dioxide positioned above the etch stop layer. The method further comprises performing at least one etching process to define an opening that extends through the stack of process layers to thereby expose a portion of the surface of the substrate, forming sidewall spacers comprised of silicon nitride in the opening in the stack of process layers, performing at least one etching process to define a trench in the substrate using the sidewall spacers as a portion of a mask during the etching process, removing the second layer of silicon dioxide, performing a thermal growth process to form a liner layer comprised of silicon dioxide on at least the sidewalls of the trench, performing at least one etching process to remove the sidewall spacers and the etch stop layer, and depositing additional material in the trench adjacent the liner layer.

In yet another illustrative embodiment, the method comprises forming a first layer of silicon dioxide on a surface of a semiconducting substrate, forming a first layer of silicon nitride on the first layer of silicon dioxide, forming a second layer of silicon dioxide on the first layer of silicon nitride, performing at least one etching process to define an opening through the first layer of silicon dioxide, the first layer of silicon nitride and the second layer of silicon dioxide to thereby expose a portion of the surface of the substrate, forming a second layer of silicon nitride above the second layer of silicon dioxide and in the opening, performing an anisotropic etching process on the second layer of silicon nitride to thereby define sidewall spacers comprised of silicon nitride in the opening, performing at least one etching process to define a trench in the substrate using the sidewall spacers as a portion of a mask during the etching process, performing at least one etching process to remove the second layer of silicon dioxide, forming a liner layer comprised of silicon dioxide on at least the sidewalls of the trench, performing at least one etching process to remove the first layer of silicon nitride and the sidewall spacers, and depositing additional material in the trench adjacent the liner layer.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a stack of process layers above a surface of a semiconducting substrate, said stack of process layers comprised of:
a first layer of insulating material formed above a surface of said substrate,
an etch stop layer positioned above said first layer of insulating material, wherein said etch stop layer has an etch selectivity with respect to said first layer of insulating material of at least 3:1, and
a second layer of insulating material positioned above said etch stop layer;
performing at least one etching process to define an opening that extends through said stack of process layers to thereby expose a portion of said surface of said substrate;
forming sidewall spacers in said opening in said stack of process layers, wherein said sidewall spacers are comprised of a material having an etch selectivity with respect to said first layer of insulating material of at least 3:1;
performing at least one etching process to define a trench in said substrate using said sidewall spacers as a portion of a mask during said at least one etching process, said trench having sidewalls;
removing said second layer of insulating material;
forming a liner layer comprised of an insulating material on at least said sidewalls of said trench;
performing at least one etching process to remove said sidewall spacers and said etch stop layer; and
forming additional material in said trench adjacent said liner layer.

2. The method of claim 1, wherein said first layer of insulating material is comprised of silicon dioxide, said etch stop layer is comprised of silicon nitride, and said second layer of insulating material is comprised of silicon dioxide.

3. The method of claim 1, wherein said step of forming said stack of process layers comprises:
performing a thermal growth process to form said first layer of insulating material on said surface of said substrate, wherein said first layer of insulating material is comprised of silicon dioxide;
performing a deposition process to form said etch stop layer on said first layer of insulating material, wherein said etch stop layer is comprised of silicon nitride; and
performing a deposition process to form said second layer of insulating material on said etch stop layer, wherein said second layer of insulating material is comprised of silicon dioxide.

4. The method of claim 1, wherein forming said sidewall spacers comprises:
depositing a layer of spacer material above said second layer of insulating material and in said opening; and
performing an anisotropic etching process on said layer of spacer material to define said sidewall spacers.

5. The method of claim 1, wherein said sidewall spacers are comprised of silicon nitride.

6. The method of claim 1, wherein removing said second layer of insulating material comprises performing at least one wet etching process to remove said second layer of insulating material.

7. The method of claim 1, wherein said liner layer is comprised of silicon dioxide.

8. The method of claim 1, wherein forming a liner layer comprises performing a thermal growth process to form a liner layer comprised of silicon dioxide on at least said sidewalls of said trench.

9. The method of claim 1, further comprising forming a sacrificial layer of silicon dioxide on at least said sidewalls of said trench and removing said sacrificial layer of silicon dioxide prior to forming said liner layer.

10. The method of claim 1, wherein forming additional material in said trench adjacent said liner layer comprises depositing at least one of silicon nitride and polysilicon in said trench.

11. A method, comprising:
forming a stack of process layers above a semiconducting substrate, said stack of process layers comprised of:
a first layer comprised of silicon dioxide formed above a surface of said substrate,
an etch stop layer positioned above said first layer of silicon dioxide, wherein said etch stop layer has an etch selectivity with respect to silicon dioxide of at least 3:1, and
a second layer comprised of an insulating material positioned above said etch stop layer;
performing at least one etching process to define an opening that extends through said stack of process layers to thereby expose a portion of said surface of said substrate;
forming sidewall spacers in said opening in said stack of process layers, wherein said sidewall spacers are comprised of a material having an etch selectivity with respect to silicon dioxide of at least 3:1;
performing at least one etching process to define a trench in said substrate using said sidewall spacers as a portion of a mask during said at least one etching process, said trench having sidewalls;
removing said second layer of insulating material;
performing a thermal growth process to form a liner layer comprised of silicon dioxide on at least said sidewalls of said trench;
performing at least one etching process to remove said sidewall spacers and said etch stop layer; and
depositing additional material in said trench adjacent said liner layer.

12. The method of claim 11, wherein said etch stop layer is comprised of silicon nitride.

13. The method of claim 11, wherein said second layer of insulating material is comprised of silicon dioxide.

14. The method of claim 11, wherein said step of forming said stack of process layers comprises:
performing a thermal growth process to form said first layer of silicon dioxide on said surface of said substrate;
performing a deposition process to form said etch stop layer on said first layer of silicon dioxide, wherein said etch stop layer is comprised of silicon nitride;
and performing a deposition process to form said second layer comprised of an insulating material on said etch stop layer, wherein said second layer of insulating material is comprised of silicon dioxide.

15. The method of claim 11, wherein forming said sidewall spacers comprises:
depositing a layer of spacer material above said second layer comprised of an insulating material and in said opening; and
performing an anisotropic etching process on said layer of spacer material to define said sidewall spacers.

16. The method of claim 11, wherein said sidewall spacers are comprised of silicon nitride.

17. The method of claim 11, wherein removing said second layer comprised of said insulating material comprises performing at least one etching process to remove said second layer of insulating material.

18. The method of claim 11, further comprising forming a sacrificial layer of silicon dioxide on at least said sidewalls of said trench and removing said sacrificial layer of silicon dioxide prior to forming said liner layer.

19. The method of claim 11, wherein depositing additional material in said trench adjacent said liner layer comprises depositing at least one of silicon nitride and polysilicon in said trench.

20. A method, comprising:
forming a stack of process layers above a semiconducting substrate, said stack of process layers comprised of:
a first layer of silicon dioxide formed above a surface of said substrate,
an etch stop layer comprised of silicon nitride positioned above said first layer of silicon dioxide, and
a second layer of silicon dioxide positioned above said etch stop layer;
performing at least one etching process to define an opening that extends through said stack of process layers to thereby expose a portion of said surface of said substrate;
forming sidewall spacers comprised of silicon nitride in said opening in said stack of process layers;
performing at least one etching process to define a trench in said substrate using said sidewall spacers as a portion of a mask during said at least one etching process, said trench having sidewalls;
removing said second layer of silicon dioxide;
performing a thermal growth process to form a liner layer comprised of silicon dioxide on at least said sidewalls of said trench;
performing at least one etching process to remove said sidewall spacers and said etch stop layer; and
depositing additional material in said trench adjacent said liner layer.

21. The method of claim 20, wherein said step of forming said stack of process layers comprises:
performing a thermal growth process to form said first layer of silicon dioxide on said surface of said substrate;
performing a deposition process to form said etch stop layer comprised of silicon nitride on said first layer of silicon dioxide; and
performing a deposition process to form said second layer of silicon dioxide on said etch stop layer.

22. The method of claim 20, wherein forming said sidewall spacers comprises:
depositing a layer of silicon nitride above said second layer of silicon dioxide and in said opening; and
performing an anisotropic etching process on said layer of silicon nitride to define said sidewall spacers.

23. The method of claim 20, wherein removing said second layer of silicon dioxide comprises performing at least one etching process to remove said second layer of silicon dioxide.

24. The method of claim 20, further comprising forming a sacrificial layer of silicon dioxide on at least said sidewalls of said trench and removing said sacrificial layer of silicon dioxide prior to forming said liner layer.

25. The method of claim 20, wherein depositing additional material in said trench adjacent said liner layer comprises depositing at least one of silicon nitride and polysilicon in said trench.

26. A method, comprising:
forming a first layer of silicon dioxide on a surface of a semiconducting substrate;
forming a first layer of silicon nitride on said first layer of silicon dioxide;
forming a second layer of silicon dioxide on said first layer of silicon nitride;
performing at least one etching process to define an opening through said first layer of silicon dioxide, said first layer of silicon nitride and said second layer of silicon dioxide to thereby expose a portion of said surface of said substrate;
forming a second layer of silicon nitride above said second layer of silicon dioxide and in said opening;
performing an anisotropic etching process on said second layer of silicon nitride to thereby define sidewall spacers comprised of silicon nitride in said opening;
performing at least one etching process to define a trench in said substrate using said sidewall spacers as a portion of a mask during said at least one etching process, said trench having sidewalls;
performing at least one etching process to remove said second layer of silicon dioxide;
forming a liner layer comprised of silicon dioxide on at least said sidewalls of said trench;
performing at least one etching process to remove said first layer of silicon nitride and said sidewall spacers; and
depositing additional material in said trench adjacent said liner layer.

27. A method, comprising:
performing a thermal growth process to form a first layer of silicon dioxide on a surface of a semiconducting substrate;
depositing a first layer of silicon nitride on said first layer of silicon dioxide;
depositing a second layer of silicon dioxide on said first layer of silicon nitride;
performing at least one etching process to define an opening through said first layer of silicon dioxide, said first layer of silicon nitride and said second layer of silicon dioxide to thereby expose a portion of said surface of said substrate;
depositing a second layer of silicon nitride on said second layer of silicon dioxide and in said opening;
performing an anisotropic etching process on said second layer of silicon nitride to thereby define sidewall spacers comprised of silicon nitride in said opening;
performing at least one etching process to define a trench in said substrate using said sidewall spacers as a portion of a mask during said at least one etching process, said trench having sidewalls;
performing at least one etching process to remove said second layer of silicon dioxide;
performing a thermal growth process to form a liner layer comprised of silicon dioxide on at least said sidewalls of said trench;
performing at least one etching process to remove said first layer of silicon nitride and said sidewall spacers; and
depositing additional material in said trench adjacent said liner layer.
